(19) United States
(12) Patent Application Publication
(10) Pub. No.: US 2013/0181344 A1
(43) Pub. Date: Jul. 18, 2013

(54) SEMICONDUCTOR MODULE, METHOD FOR MANUFACTURING THE SEMICONDUCTOR MODULE, AND MOBILE APPARATUS

(71) Applicant: Sanyo Electric Co., Ltd., Osaka (JP)

(72) Inventors: Yasuyuki Yanase, Hashima-shi (JP); Ryosuke Usui, Ichinomiya-shi (JP)

(73) Assignee: SANYO ELECTRIC CO., LTD., Osaka (JP)

(21) Appl. No.: 13/691,139

(22) Filed: Nov. 30, 2012

Related U.S. Application Data
(63) Continuation of application No. PCT/JP2011/062536, filed on May 31, 2011.

(30) Foreign Application Priority Data
May 31, 2010 (JP) 2010-125302

(51) Int. Cl. H01L 23/00; H01L 23/498

(52) U.S. Cl. CPC H01L 24/11; H01L 23/49811
USPC 257/737; 438/121

(57) ABSTRACT

Bump electrodes and wiring layers are formed by selectively removing a copper sheet while the copper sheet is being held on a supporting base by an adhesion layer. Subsequently, a device mounting board is formed by laminating an insulating resin layer in such a manner that Au/Ni layers are exposed on the bump electrodes and the adhesion layer. The device mounting board and a semiconductor device held on the supporting base are temporarily press-bonded to each other and then the supporting base and the adhesion layer are removed. Then the device mounting board and the semiconductor device are finally and permanently press-bonded together.

### BACKGROUND OF THE INVENTION

1. Field of the Invention

The present invention relates to semiconductor module mounted on a device mounting board and a method for the semiconductor module.

2. Description of the Related Art

Portable electronic devices, such as mobile phones, PDAs, DVCs and DSCs, are gaining increasing sophistication in functions and features. And to be accepted by the market, they have to be smaller in size and lighter in weight, and for the realization thereof, there is a growing demand for highly-integrated system LSIs. On the other hand, these electronic devices are desired to be easier or handier to use, and therefore the LSIs used in those devices are required to be more functionally sophisticated and better performing. For this reason, the higher integration of LSI chips is causing increases in I/O count, which in turn generates demand for smaller packages. To satisfy both these requirements, it is strongly desired that semiconductor packages suited for the high board density packaging of semiconductor components be developed. To meet such needs, a variety of packaging technologies called CSP (Chip Size Package) are being developed.

### RELATED ART LIST

(1) Japanese Unexamined Patent Application Publication (Kokai) No. Hei10-22339.

As the semiconductor module is made smaller in size or miniaturized, a wiring substrate that constitutes the semiconductor module, namely the wiring substrate in the device mounting board, is getting denser and thinner. Accordingly, the occurrence of creases in a metallic sheet used to form a wiring layer in a fabrication process is likely to cause a drop in the fabrication yield. This makes it hard to handle the wiring layer during processing and also hard to handle a process performed when the device mounting board is pressed-bonded to a semiconductor device.

### SUMMARY OF THE INVENTION

The present invention has been made in view of the foregoing problems to be resolved, and a purpose thereof is to provide a technology capable of making it easy to handle the component members when the semiconductor modules are manufactured and capable of simplifying the process of manufacturing the semiconductor modules.

One embodiment of the present invention relates to a method for fabricating a semiconductor module. The method for fabricating a semiconductor module includes: a process of forming a wiring layer, where a substrate electrode is provided, by selectively removing a metallic sheet held on a supporting base; and a process of forming a device mounting board, which includes the wiring layer, the substrate electrode, and an insulating resin layer, by forming the insulating resin layer on the supporting base in a manner such that a top face itself of the substrate electrode or a metallic layer disposed on the top face of the substrate electrode or is exposed, wherein, the process of forming the wiring layer includes a process where the wiring layer is formed in a tapered shape such that the end surface of the wiring layer enters inside a wiring layer forming region as the end surface thereof approaches the semiconductor device.

### BRIEF DESCRIPTION OF THE DRAWINGS

Embodiments will now be described by way of examples only, with reference to the accompanying drawings which are meant to be exemplary, not limiting, and wherein like elements are numbered alike in several Figures in which:

FIG. 1 is a schematic cross-sectional view illustrating a structure of a semiconductor module according to a first embodiment of the present invention;

FIGS. 2A to 2C are schematic cross-sectional views showing a process in a first method for manufacturing a semiconductor module;

FIGS. 3A to 3C are schematic cross-sectional views showing a process in a first method for manufacturing a semiconductor module;

FIGS. 4A to 4C are schematic cross-sectional views showing a process in a first method for manufacturing a semiconductor module;

FIGS. 5A and 5B are schematic cross-sectional views showing a process in a first method for manufacturing a semiconductor module;

FIGS. 6A and 6B are schematic cross-sectional views showing a process in a first method for manufacturing a semiconductor module;

FIGS. 7A and 7B are schematic cross-sectional views showing a process in a first method for manufacturing a semiconductor module;

FIGS. 8A and 8B are schematic cross-sectional views showing a process in a second method for manufacturing a semiconductor module;

FIGS. 9A to 9C are schematic cross-sectional views showing a process in a third method for manufacturing a semiconductor module;

FIG. 10A is a schematic cross-sectional view showing a process in a third method for manufacturing a semiconductor module;

FIG. 10B is a schematic cross-sectional view illustrating a structure of a semiconductor module according to a second embodiment of the present invention;

FIG. 11A is a schematic cross-sectional view showing a process in a fourth method for manufacturing a semiconductor module;

FIG. 11B is a schematic cross-sectional view illustrating a structure of a semiconductor module according to a third embodiment of the present invention;

FIG. 12 is a cross-sectional view illustrating a structure of a solar cell in a related art; and

FIGS. 13A and 13B are diagrams each showing a structure of a solar cell according to an embodiment of the present invention.

### DETAILED DESCRIPTION OF THE INVENTION

Hereinbelow, the preferred embodiments will be described with reference to the accompanying drawings. Note that in all of the Figures the same reference numerals are given to the same components and the description thereof is omitted as appropriate.

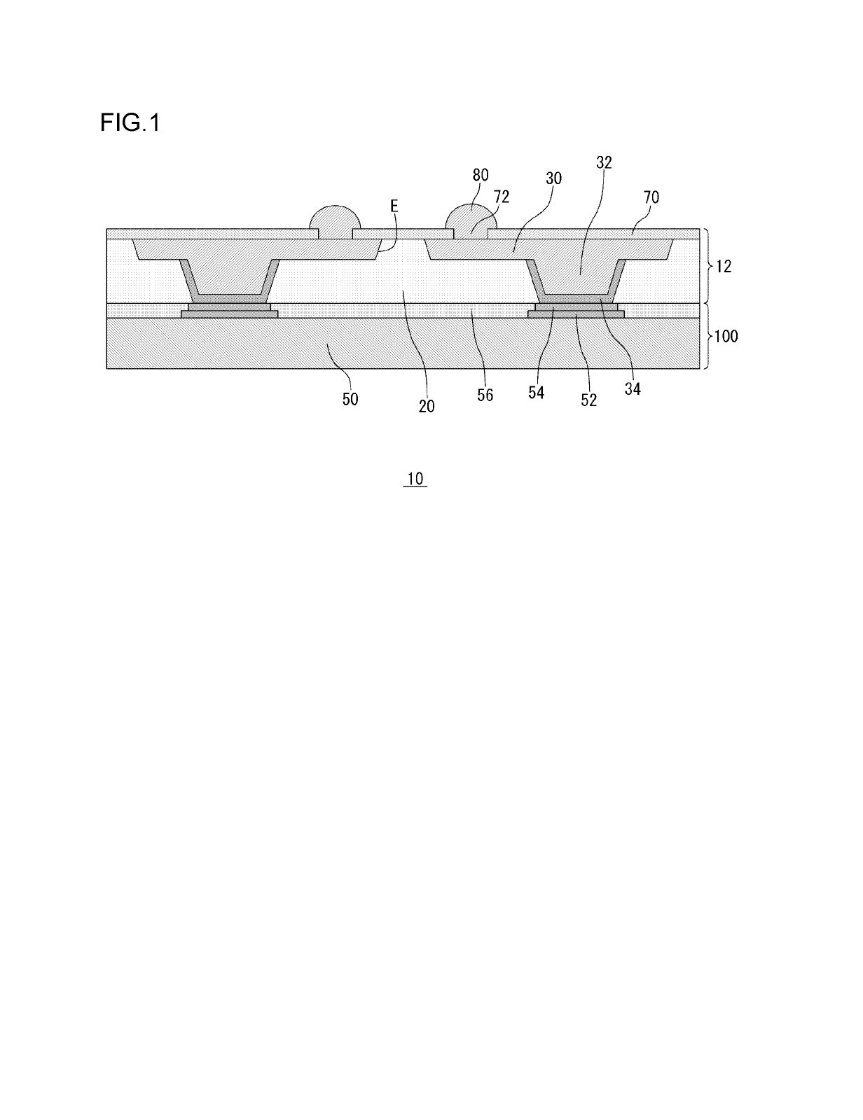

FIG. 1 a schematic cross-sectional view illustrating a structure of a semiconductor module 10 according to a first embodiment of the present invention. The semiconductor module 10 includes a device mounting board 12 and a semiconductor device 100 bonded to the device mounting board 12.

The device mounting board 12 includes an insulating resin layer 20 formed of an insulating resin layer 20, a wiring layer 30 provided on one of main surfaces of the insulating resin layer 20, and a plurality of bump electrodes 32, which electrically connect to the wiring layer 30 and protrude from the wiring layer 30 toward the insulating resin layer 20.

The insulating resin layer 20 may be formed of a thermosetting resin such as a melamine derivative (e.g., BT resin), liquid-crystal polymer, epoxy resin, PPE resin, polyimide resin, fluorine resin, phenol resin or polyamide bismaleimide, or the like. From the viewpoint of improving the heat radiation of the semiconductor module 10, it is desirable that the insulating resin layer 20 has a high thermal conductivity. In this respect, it is preferable that the insulating resin layer 20 contains, as a high thermal conductive filler, silver, bismuth, copper, aluminum, magnesium, tin, zinc, or an alloy of two or more elements selected from thereamong.

The wiring layer 30, which is provided on one main surface of the insulating resin layer 20, is formed of a conducive material, preferably of a rolled metal or more preferably of a rolled copper. A plurality of bump electrodes 32 are, in a protruding manner, on an insulating resin layer 20 side. In the first embodiment, the wiring layer 30 and the bump electrode 32 are formed integrally with each other, but the present embodiment is not limited thereto.

An end surface E of the wiring layer 30 is in contact with the insulating resin layer 20. The end surface E of the wiring layer 30 is formed in a tapered shape such that the end surface E thereof enters inside a wiring layer forming region as the end surface E thereof approaches the semiconductor device 100. Different from a case of the tapered shape where the end surface E of the wiring layer 30 overhangs outward as the end surface E thereof comes close to the semiconductor device 100, the area where a solder ball 80 described later, which is an external connection electrode, is formed can be made larger if used is the shape according to the present embodiment. Thus, the external connection electrode having a large area connected to the wiring layer 30 can be formed. Since the contact area between the external connection electrode and the wiring layer is large, the heat generated from the semiconductor device can be efficiently radiated to the outside and, at the same time, the adhesion between the wiring layer and the external connection electrode can be improved.

The planar view of the bump electrode 32 is a round shape, and each bump electrode 32 has a side surface that is shaped with a diameter smaller toward a head portion. The side surface of the bump electrodes 32 may be tilted in the same direction as the tilted direction of the end surface E of the wiring layer 30. In such a case, a bottleneck (hindrance portions that hinder the radiation of heat) in a diffusion path through which the heat generated from the semiconductor device can dissipate can be eliminated, so that the heat can be efficiently radiated. Note here that the shape of the bump electrode 32 is not limited to any particular shape and may be, for instance, in the shape of a cylinder with a predetermined diameter. Also, the bump electrode 32 may be polygonal, such as quadrangular, when viewed planarly.

An Au/Ni layer 34 is provided on the top face and the side surface of the bump electrode 32. The Au/Ni layer 34 is comprised of an Au layer, which is the exposed surface of the Au/Ni layer 34, and a Ni layer, which is held between the Au layer and the top face of the bump electrode 32.

A protective layer 70 is disposed on a main surface of the wiring layer 30 opposite to the second insulating resin layer 20. The protective layer 70 protects the wiring layer 30 against oxidation or the like. The protective layer 70 may be a solder resist layer, for instance. An opening 72 is formed in a predetermined region of the protective layer 70, and the wiring layer 30 is partially exposed by the opening 72. A solder ball 80 is formed within the opening 72 as the external connection electrode. And the solder ball 80 and the wiring layer 30 are electrically connected to each other. The position in which the solder balls 80 are formed, namely a forming region of the opening 72, are targeted positions where circuit wiring is extended through a rewiring (the wiring layer 30).

The semiconductor device 100 includes a semiconductor substrate 50, device electrodes 52, Au/Ni layers 54, and a protective layer 56. The device electrode 52, the Au/Ni layer 54, and the protective layer 56 are formed on one main surface of the semiconductor substrate 50. More specifically, the semiconductor substrate 50 is a silicon substrate such as a P-type silicon substrate. A predetermined integrated circuit (not shown) and the device electrode 52 positioned in an outer periphery of the predetermined integrated circuit are formed on one main surface of the semiconductor substrate 50. The device electrode 52 is made of a metal such as aluminum or copper. The insulating-type protective layer 56 to protect the semiconductor substrate 50 is formed in a region on the main surface of the semiconductor substrate 50 excepting the device electrodes 52. The protective layer 56 to be used may be a silicon dioxide film (SiO₂), a silicon nitride film (SiN) or polyimide (PI), for instance. The Au/Ni layer 54 is formed on top of the device electrode 52 such that the Au layer is an exposed surface.

Gold of the Au/Ni layer 34 provided on the top face of the bump electrode 32 and gold of the Au/Ni layer 54 provided on the surface of the device electrode 52 are Au—Au bonded to each other. Thereby, the bump electrode 32 and the element electrode 52 corresponding to this bump electrode 32 are electrically connected to each other. The structure where the Au/Ni layer 34 and the Au/Ni 54 are Au—Au bonded together contributes to an improved electric connection reliability between the bump electrode 32 and the device electrode 52 corresponding thereto.

The structure and arrangement of the semiconductor module 10 according to the present embodiment makes it easier for the insulating resin layer 20 disposed between the wiring layer 30 and the semiconductor device 100 to flow along the tapered end surface E of the wiring layer 30 when the device mounting board 12 and the semiconductor device 100 are press-bonded to each other. Thus the insulating resin layer 20 is filled into every corner of a space between the wiring layer 20 and the semiconductor device 100. As a result, the adhesion between the insulating resin layer 20 and the wiring layer 30 and the adhesion between the insulating layer 20 and the protective layer 70 can be improved.

When it is checked that the wiring wire 30 is not short-circuited using a microscope, it is only necessary to observe the wiring wire 30 by focusing on an end located far from the semiconductor device 100 in the end surface E. This can reduce the number of steps otherwise required for the checking.

(First Method for Fabricating a Semiconductor Module)

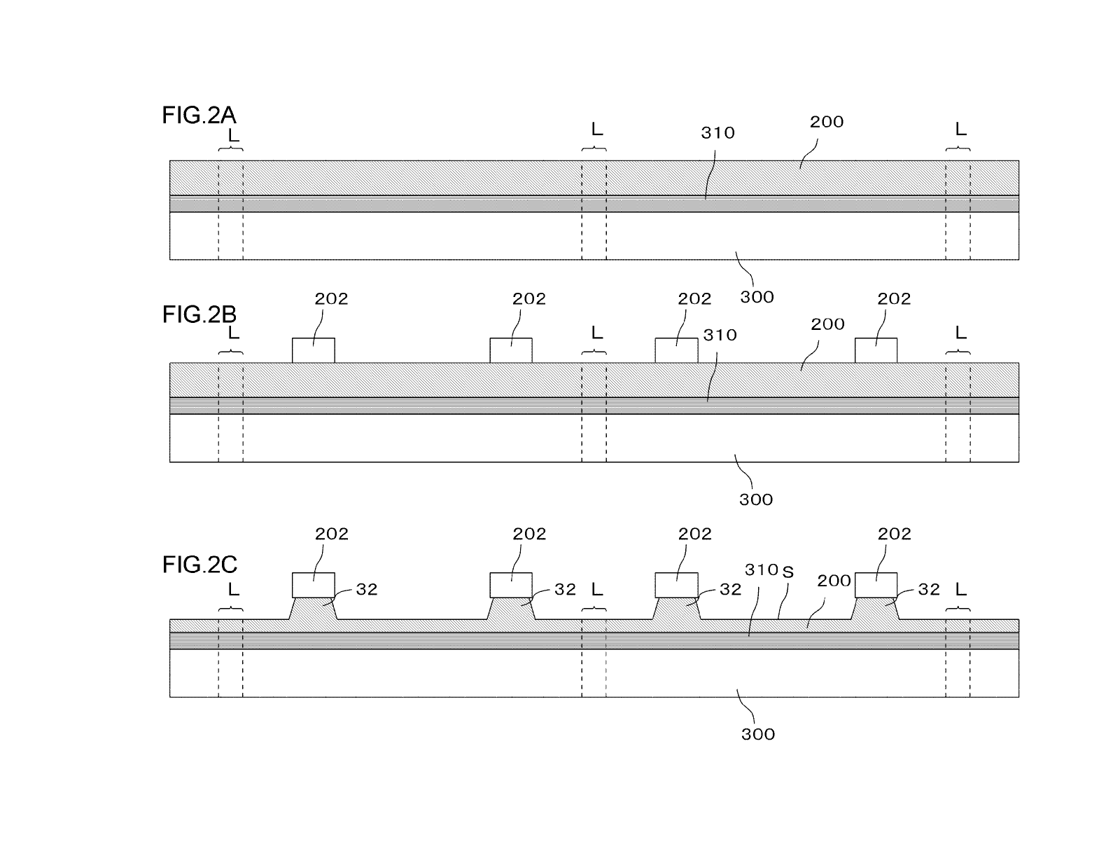

Referring to FIGS. 2A to FIG. 7B, a first method for fabricating a semiconductor module 10 according to an embodiment will be described.

As illustrated in FIG. 2A, a copper sheet 200 is first prepared as a metallic sheet having a thickness approximately equal to the sum of the height of the bump electrode 32 and the thickness of the wiring layer 30. The thickness of the copper sheet 200 is about 40 μm, for instance. A rolled metal, formed of a rolled copper, or electrolytic copper foil may be used as the copper sheet 200. The copper sheet 200 is bonded to a supporting base 300 using an adhesive layer 310. Note here that the supporting base 300 serves to function as a supporting member. The substrate 300 is preferably transparent, and a glass substrate or PET (polyethylene terephthalate) film may be suitable as the substrate 300.

Then, as shown in FIG. 2B, resists 202 are formed selectively in alignment with a pattern that corresponds to a predetermined region for use in formation of the bump electrodes 32 as shown in FIG. 1 in each demarcated region surrounded by scribe lines L, using a lithography method. More specifically, a resist film having a predetermined film thickness is affixed to the copper sheet 200 by using a laminator apparatus, and it is then subjected to exposure using a photo mask having a pattern of bump electrodes 1032. After this, the resists 202 are selectively formed on top of the copper sheet 200 by a development. To improve the adhesion of the resists 202 to the copper sheet 200, it is desirable that a pretreatment, such as grinding and cleaning, be performed as necessary on the surface of the copper sheet 200 before the lamination of the resist film thereon.

Then, as shown in FIG. 2C, using the resists 202 as a mask, the bump electrodes 32 of a predetermined pattern protruding from a surface S of the copper sheet 200 is formed by performing the wet etching on the copper sheet 200, in which a chemical such as ferric chloride solution or the like is used. In so doing, the bump electrodes 32 are formed such that each bump electrode 32 has a tapered side surface whose diameter (dimension) decreases as the side surface of the bump electrode 32 approaches the tip end thereof. The height of the bump electrode 32 may be 20 μm for instance. Subsequently, the resists 202 and the resist protective film are removed using a remover. Through a process as described above, the bump electrodes 32 are integrally formed on the copper sheet 200 through a process as described above. Note here that the bump electrode 32 is an example of “substrate electrode” that is an electrode on a device mounting board side.

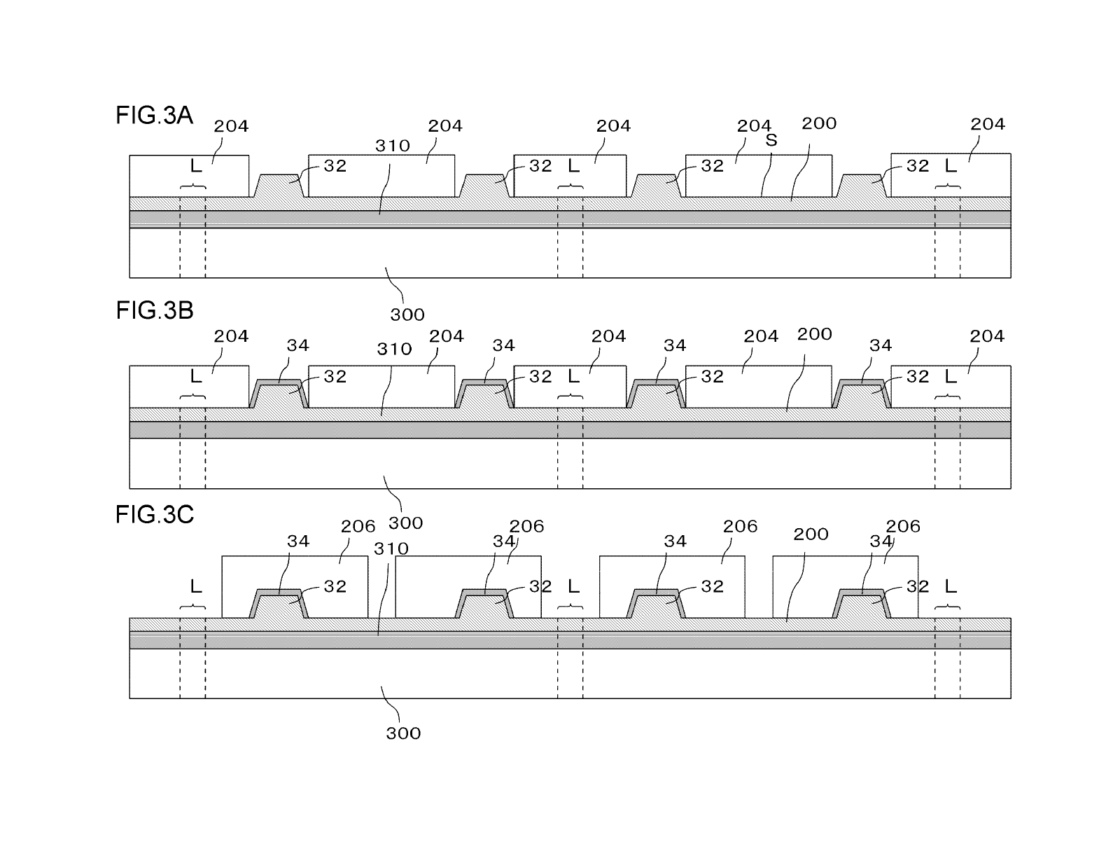

Then, as shown in FIG. 3A, resists 204 having openings through which the bump electrodes 32 are exposed are selectively formed using the lithography method. More specifically, a resist film having a predetermined film thickness is affixed to the copper sheet 200 by using the laminator apparatus, and it is then subjected to exposure using a photo mask that has such a pattern as to mask the openings corresponding to the bump electrodes 32. After this, the resists 204 are selectively formed on top of the copper sheet 200 by a development.

Then, as shown in FIG. 3B, the Au/Ni layers 34 are formed on the top face and the side surface of the bump electrodes 32 that are exposed within the openings provided in the resists 204, by electrolytic plating or electroless plating. In the Au/Ni layer 34, the Au layer is the exposed surface of the Au/Ni layer 34, and the Ni layer is held between the Au layer and the top face of the bump electrode 32. In the Au/Ni layer 34, the thickness of Au layer may be 0.25 μm, for instance, and the thickness of the Ni layer may be 1 to 3 μm, for instance. Note that, instead of the Au/Ni layer 34, a metallic layer may be formed on the top face and the side surface of the bump electrode 32 using gold paste.

Then, as shown in FIG. 3C, resists 206 corresponding to the wiring layer forming regions are selectively formed by the lithography method. More specifically, a resist film having a predetermined film thickness is affixed to the copper sheet 200 by using the laminator apparatus, and it is then subjected to exposure using a photo mask that has a pattern corresponding to the wiring layer forming regions. After this, the resists 206 are selectively formed on top of the copper sheet 200 by a development.

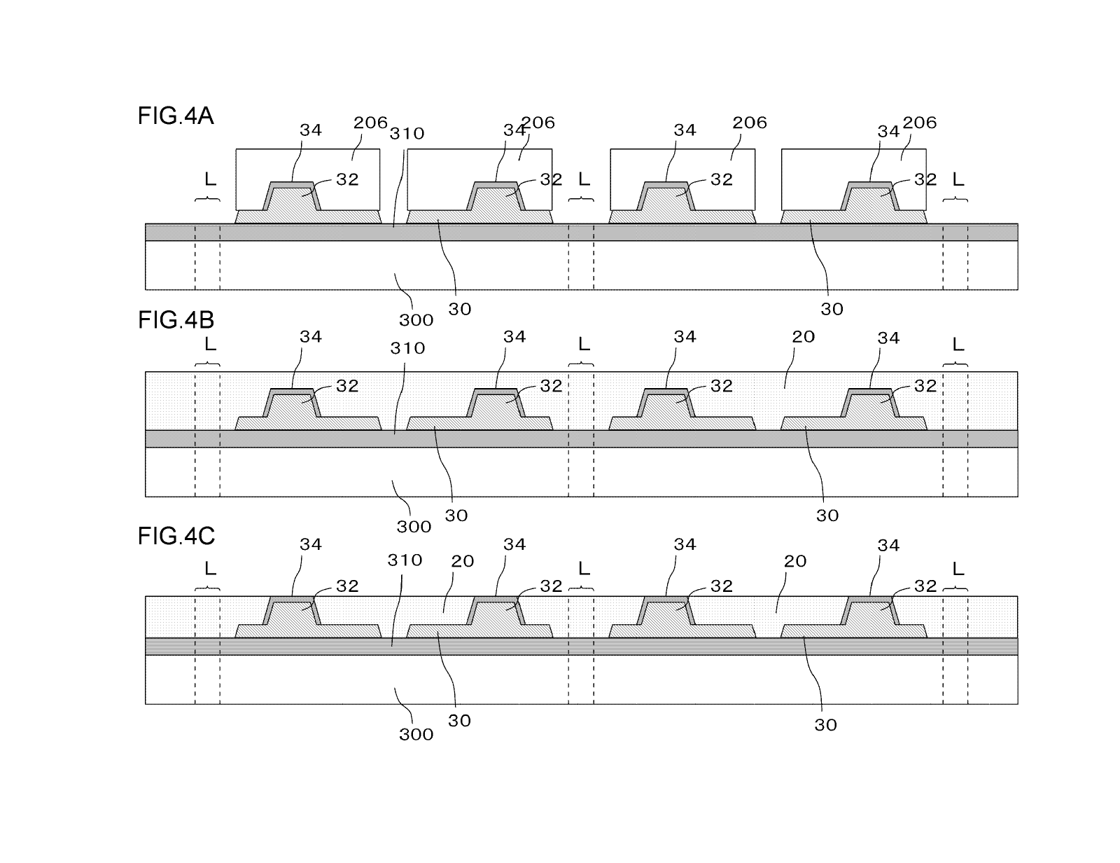

Then, as shown in FIG. 4A, using the resists 206 as a mask, the copper sheet 200 is processed into a predetermined wiring pattern by performing the wet etching on the copper sheet 200, in which a chemical such as ferric chloride solution or the like is used. This forms wiring layers (rewiring) 30. As a result, the wiring layers 30 with which predetermined bump electrodes 32 are integrally formed are formed. In other words, the bump electrode 32 and the wiring layer 30, which are made of the same material, are formed continuously as a single body. As described above, the thickness of the wiring layer 30 is 20 μm if the thickness of the unprocessed copper sheet 200 is 40 μm and the height of the bump electrode 32 is 20 μm.

Then, as shown in FIG. 4B, the insulating resin layer 20 is laminated on the wiring layers 30, the bump electrodes 32 and the adhesion layers 310, using a roll laminator or hot press machine. For example, a thermosetting, epoxy-based adhesive resin film may be used as the insulating resin layer 20. The insulating resin layer 20 to be laminated may have a thickness enough to cover the Au/Ni layer 34 formed on the top surface of the bump electrode 32. Since the epoxy-based adhesive resin film is bonded to the semiconductor substrate 50 in a process described later, the temperature of the epoxy-based adhesive resin film at the time it is stacked on the wiring layers 30, the bump electrodes 32 and the adhesion layers 310 is preferably a temperature of 100° C. or below which does not cause the epoxy-based adhesive resin film to become completely hardened.

Then, as shown in FIG. 4C, the insulating resin layer 20 is turned into thin film by the use of O₂ plasma etching or polishing so that the Au/Ni layer 34 provided on the top surface of the bump electrode 32 is exposed and the top surface of the bump electrode 32 is coplanar with the exposed surface of the insulating resin layer 20. This forms the device mounting board 12 comprised of the wiring layers 30, the bump electrodes 32 and the insulating resin layer 20.

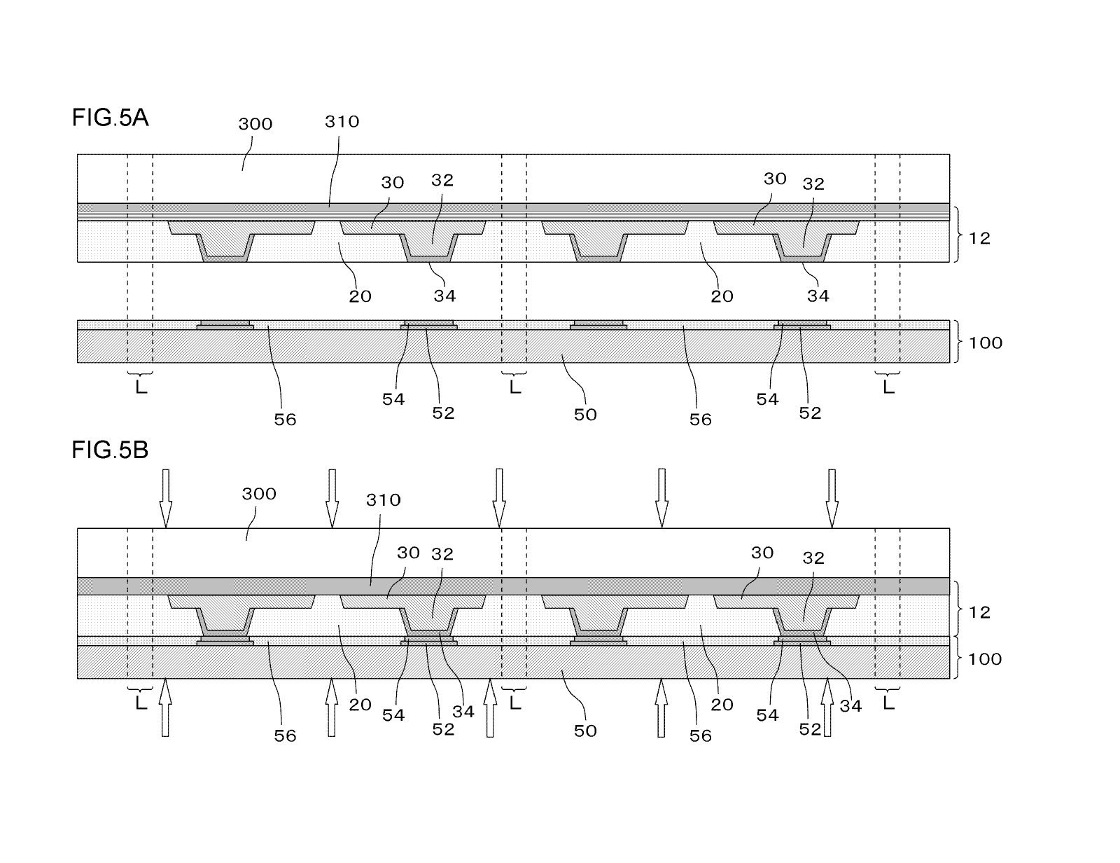

Then, as shown in FIG. 5A, prepared is a semiconductor substrate 50 where the device electrodes 52, the Au/Ni layers 54 and the protective layer 56 are formed on one main surface. More specifically, a predetermined integrated circuit is formed on one main surface of the semiconductor substrate 50, such as a P-type silicon substrate, and the device electrodes 52 are formed in the outer periphery of the integrated circuit by the use of a semiconductor manufacturing process that combines known techniques including lithography, etching, ion implantation, film formation, thermal processing and so forth. The device electrode 52 is made of a metal such as aluminum or copper. The insulating protective layer 56 to protect the semiconductor substrate 50 is formed on the main surface of the semiconductor substrate 50 excluding the electrode electrodes 52. As the protective layer 56, a silicon dioxide film (SiO₂), a silicon nitride film (SiN), a polyimide (PI) or the like is preferably used. The Au/Ni layer 54 is formed on top of the device electrode 52 such that the Au layer is an exposed surface. The structure of the Au/Ni layer 54 and the method for forming the Au/Ni layer 54 are similar to those of the Au/Ni layer 34. And the Au/Ni layer 54 may be formed such that a mask having the openings where the surfaces of the device electrodes 52 are exposed is formed and then the electrolytic plating or electroless plating is performed on the inside the openings with the mask formed thereon.

Then, as shown in FIG. 5B, the positioning of the Au/Ni layers 54 provided on the device electrodes 52 and the Au/Ni layers 34 provided on top of the bump electrodes 32 in association with the respective Au/Ni layers 54 is done. Then the wiring substrate 12 and the semiconductor substrate 50 are temporarily bonded to each other by the use of a press machine. The time duration and the pressure used in this process where the device mounting board 12 and the semiconductor device 100 are bonded to each other are three minutes and 1 MPa, respectively, for instance.

At this stage, the wiring layers 30 have already been patterned and the semiconductor substrate 50 is visible, in an area where the wiring layers 30 are not provided, through the supporting base 300, the adhesion layer 310 and the insulating layer 20. Thus, with provision of alignment marks (not shown) on the semiconductor substrate 50, the device mounting board 12 and the semiconductor substrate 50 can be positioned while the alignment marks on a semiconductor substrate 50 side are directly observed.

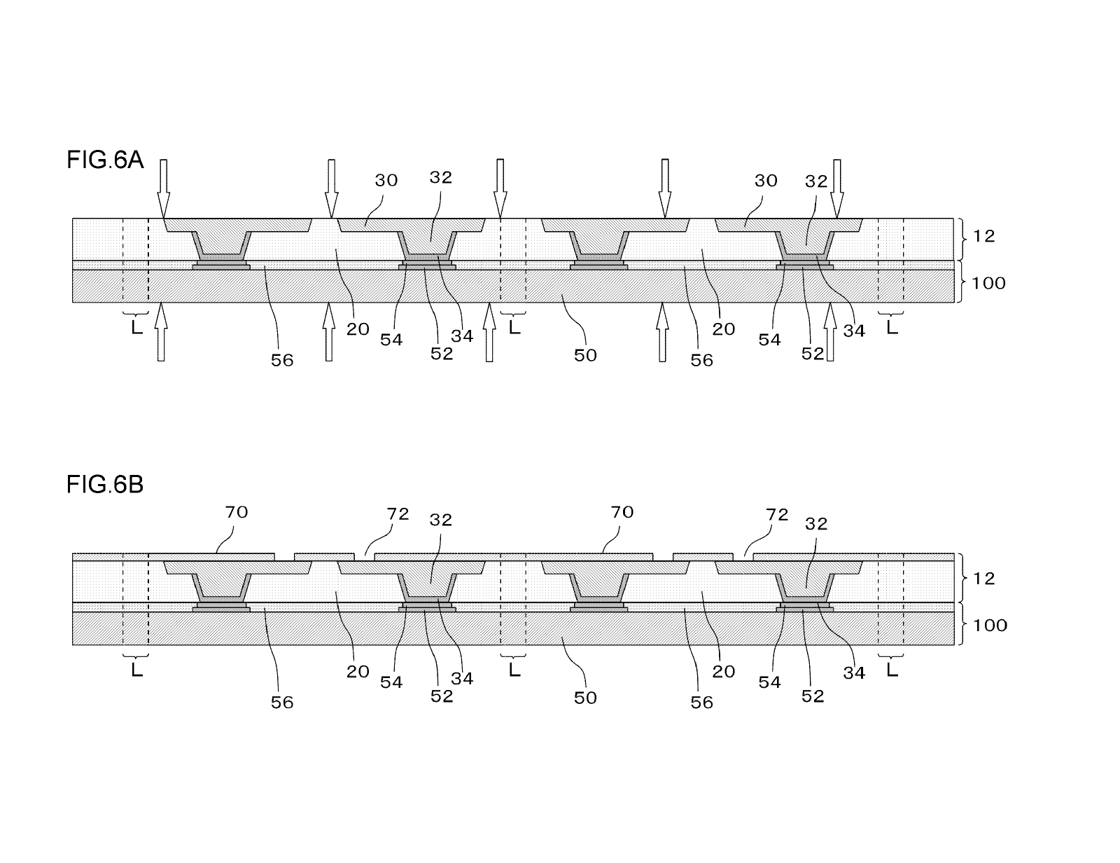

Then, as shown in FIG. 6A, the supporting base 300 and the adhesion layer 310 are removed and then the device mounting board 12 and the semiconductor device 100 are now finally and permanently press-bonded to each other using the press machine. In so doing, the insulating resin layer 20 is hardened. The time duration and the pressure used in this process where the device mounting board 12 and the semiconductor device 100 are finally press-bonded to each other may be ten minutes and 10 MPa, respectively, for instance. Note that this final press-bonding process may be carried out simultaneously with the aforementioned temporarily press-bonding process.

With the Au/Ni layer 34 provided on the top face of the bump electrode 32 being exposed, the device mounting board 12 and the semiconductor device 100 are finally and permanently press-bonded to each other. This suppresses residues from remaining between the Au/Ni layer 34 and the Au/Ni layer 54 and therefore the electric connection reliability between the bump electrodes 32 and the device electrodes 52 can be improved.

Then, as shown in FIG. 6B, a protective layer (photo solder resist layer) 70 is stacked on top of the wiring layer 30 and the exposed insulating resin layer 20. Then, the openings 72 are provided in predetermined regions (mounting regions of solder balls) of the protective layer 70 by using the photolithography method. The protective layer 70 functions as a protective film for the wiring layer 30. Epoxy resin or the like is used for the protective layer 70, and the film thickness of the protective layer 70 is about 30 μm, for instance.

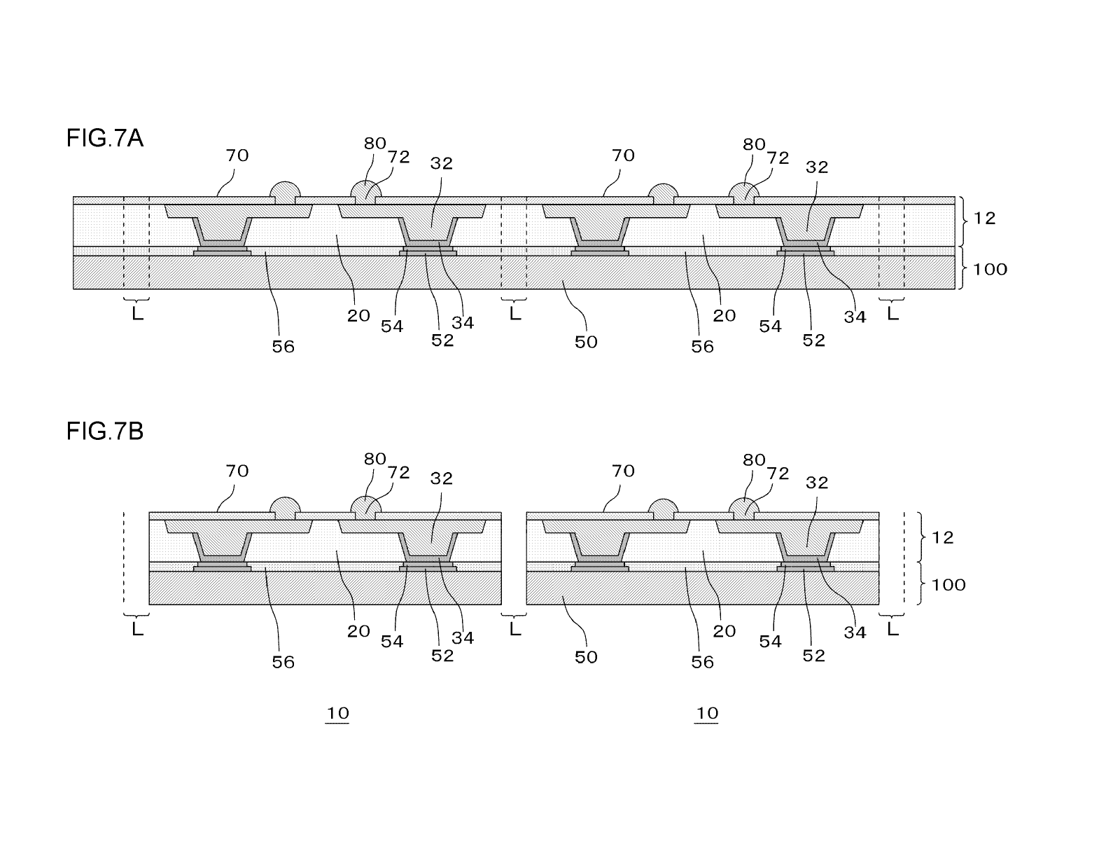

Then, as shown in FIG. 7A, the solder balls 80 are placed in the openings 72 of the protective layer 70, by using a screen printing method. More specifically, the solder balls 80 are formed in such a manner that a soldering paste, which is a pasty mixture of resin and solder material, is printed in desired positions through a screen mask and then the printed paste is heated to a solder melting point.

Then, as illustrated in FIG. 7B, a semiconductor assembly in which the semiconductor modules 10 are integrally formed is diced into a plurality of individual modules 10 by performing a dicing process along scribe lines L.

Through the processes as described above, the semiconductor modules 10 according to the first embodiment are manufactured. In the above-described method for manufacturing the semiconductor module 10, the bump electrodes 32, the Au/Ni layers 34 and the wiring layers 30 are formed while the copper sheet 200 is being supported by the supporting base 300. Thus, the handling of the copper sheet 200 in these processes of forming the bump electrodes 32, the Au/Ni layers 34 and the wiring layers 30 is easier and therefore the possibility that the wiring layers 30 and the bump electrodes 32 may be damaged can be reduced. As a result, the manufacturing yield of the semiconductor modules can be improved.

When the device mounting board 12 is finally press-bonded to the semiconductor device 100, the wiring layers 30 have already been formed in the device mounting board 12 by that time and therefore no extra metallic portion available for the formation of the wiring layer 30. Thus, the warping otherwise caused when the device mounting board 12 is finally press-bonded to the semiconductor device 100 can be prevented.

Also, it is not necessary to adjust the thickness of the copper sheet 200 by etching the copper sheet 200 down to have the thickness of the wiring layer 30 before the formation of the wiring layer 30 out of the copper sheet 200. Thus the manufacturing time can be reduced and the variation in the thickness of the wiring layers 30 can be suppressed.

In this fabrication method as described above, the Au/Ni layer 34s are covered with the insulating resin layer 20 before the insulating resin layer 20 is turned into thin film and then the Au/Ni layers 34 formed on the top face of the bump electrodes 32 are exposed (see FIG. 4A and FIG. 4B). However, the method for forming the insulating resin layer 20 is not limited to this method. For example, the viscosity and the application quantity of the insulating resin layer 20 may be adjusted and thereby the insulating resin layer 20 may be stacked in such a manner that the Au/Ni layers 34 formed on the top face of the bump electrodes 32 are exposed. Also, the insulating resin layer 20 may be formed, as follows, such that the Au/Ni layers 34 are exposed. That is, the insulating resin layer 20 is laminated as a photosensitive resin, then it is subjected to exposure and development by masking the Au/Ni layers 34 formed on the top face of the bump electrodes 32.

### (Second Method for Fabricating a Semiconductor Module)

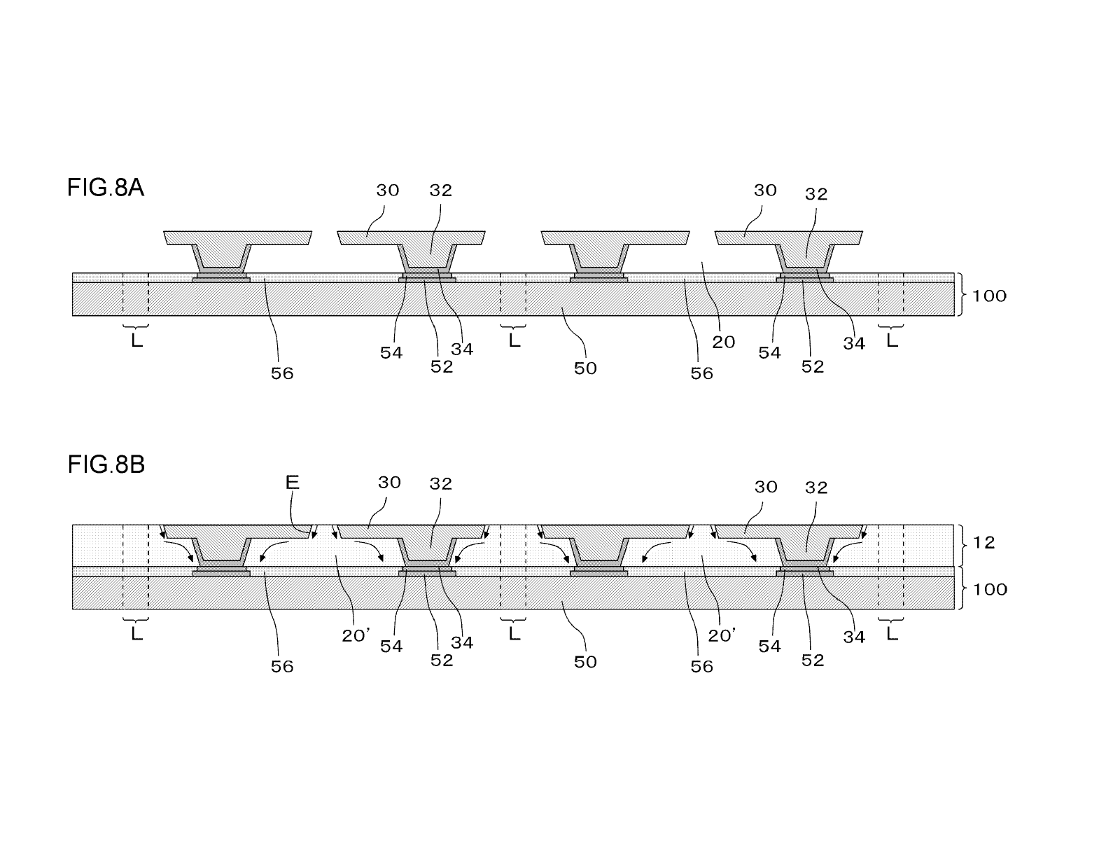

A second method for fabricating a semiconductor module 10 is the same as the second method up to the process of FIG. 6A. In the second method for fabricating the semiconductor module 10, the insulating resin layer 20 is removed, as shown in FIG. 8A, using a solvent, such as NAOH and acetone, and O₂ plasma after the process of FIG. 6A.

Then, as illustrated in FIG. 8B, an insulating resin layer 20′ is injected into a space between the wiring layer 30 and the semiconductor device 100. The insulating resin layer 20′ used in this process shown in FIG. 8B is an insulating resin layer whose content percentage of fillers having a high thermal conductivity is higher than that of the insulating resin layer 20 and whose adhesion strength is higher than that of the insulating resin layer 20, for instance, and is of a higher performance than the insulating resin layer 20. The arrows indicated in FIG. 8B schematically illustrate the flows of the insulating resin layers 20 injected.

In this manner, the insulating resin layer 20 is replaced by the high-performance insulating resin layer 20′. Then, similar to the first method for fabricating the semiconductor module, the processes shown in FIG. 6B to FIG. 7B are carried out. This produces a semiconductor module 10 structured such that in the structure of FIG. 1 the insulating resin layer 20 is replaced by the high-performance insulating resin layer 20′.

A description is now given hereunder of advantageous effects achieved by employing the second method for fabricating the semiconductor module. The end surface E of the wiring layer 30 is formed in a tapered shape such that the end surface E thereof enters inside the wiring layer forming region as the end surface E thereof gets closer to the semiconductor device 100. Also, the bump electrode 32 is of a shape such that the diameter thereof becomes smaller toward the head portion thereof. In other words, the end surface of the wiring layer 30 and the side surface of the bump electrode 32 are of a tapered shaped such that an opening section (space) surrounded by the wiring layer 30, the bump electrode 32 and the semiconductor device 100 becomes wider as this space approaches the semiconductor device 100. Accordingly, the insulating resin layer 20′ smoothly flows into the opening section when the insulating resin layer 20′ is injected thereinto. This structure and profile suppress the occurrence of the void formed between the wiring layer 30, the bump electrode 32 and the semiconductor device 100. As a result, the manufacturing yield and the operation reliability of the semiconductor modules can be improved.

Also, the content percentage of fillers in the insulating resin layer 20 used in the final press-bonding process is set to a relatively low value. Thereby, when the bump electrode 32 and the insulating resin layer 20 are bonded together through the Au—Au bonding, the possibility that the fillers in the insulating resin layer remain in the bonding interface can be reduced. Thus, the insulating resin layer 20 is replaced by the insulating resin layer 20′ whose performance is higher than that of the insulating resin layer 20 on the condition that the connection reliability between the bump electrode 32 and the device electrode 52 has been assured. Hence, the connection reliability can be improved and, at the same time, a high functionality of insulating resin layer can be achieved.

(Third Method for Fabricating a Semiconductor Module)

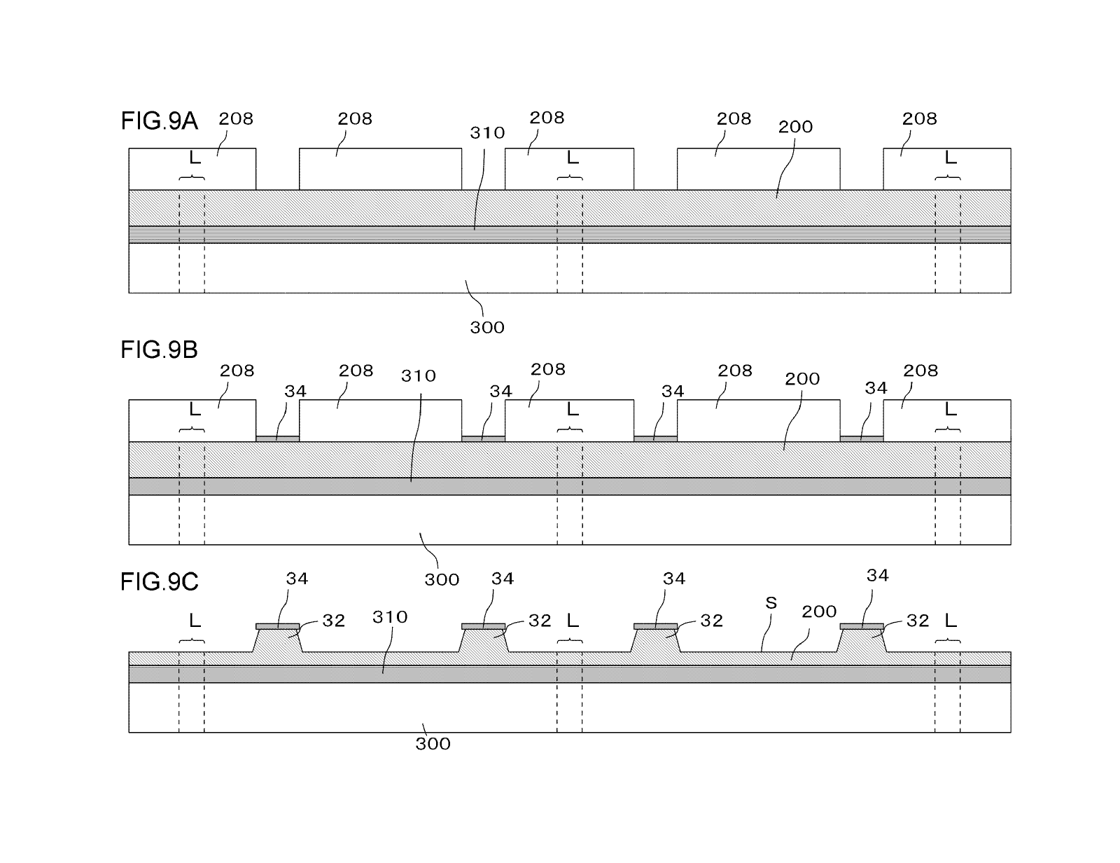

As illustrated in FIG. 9A, formed are resists 208 having openings in which Au/Ni layer forming regions corresponding to their respective device electrodes are exposed.

Then, as shown in FIG. 9B, the Au/Ni layers 34 are formed within the openings by electrolytic plating or electroless plating.

Then, as shown in FIG. 9C, the resists 208 are removed and then the bump electrodes 32 are formed by performing the wet etching on the copper sheet 200 using the Au/Ni layers 34 as a mask.

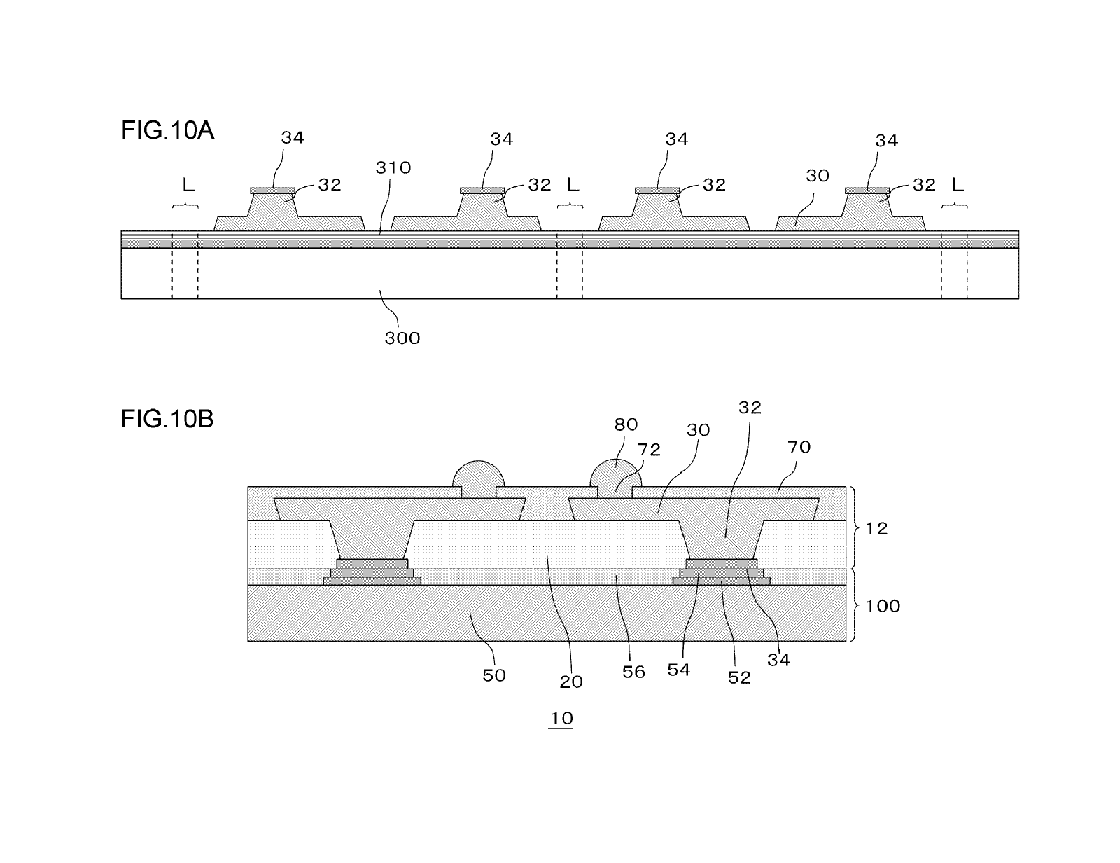

Then, as shown in FIG. 10A, the wiring layers 30 are formed by processing the copper sheet 200 into a predetermined wiring pattern using a lithography method and an etching method.

Subsequently, the processes similar to those shown in FIGS. 4A to 7B may be performed to manufacture a semiconductor module 10 according to a second embodiment as shown in FIG. 10B. The semiconductor module according to the second embodiment has the same structure as the semiconductor module 10 according to the first embodiment except that the Au/Ni layer 34 is provided on only the top surface of the bump electrode 32.

In the third method for fabricating a semiconductor module, the Au/Ni layers 34 also serves as the mask used to form the bump electrodes 32 out of the copper sheet 200, the process otherwise required for the formation and the removal of a mask can be omitted. This can further simplify the manufacturing process and also reduce the manufacturing time and the manufacturing cost.

(Fourth Method for Fabricating a Semiconductor Module)

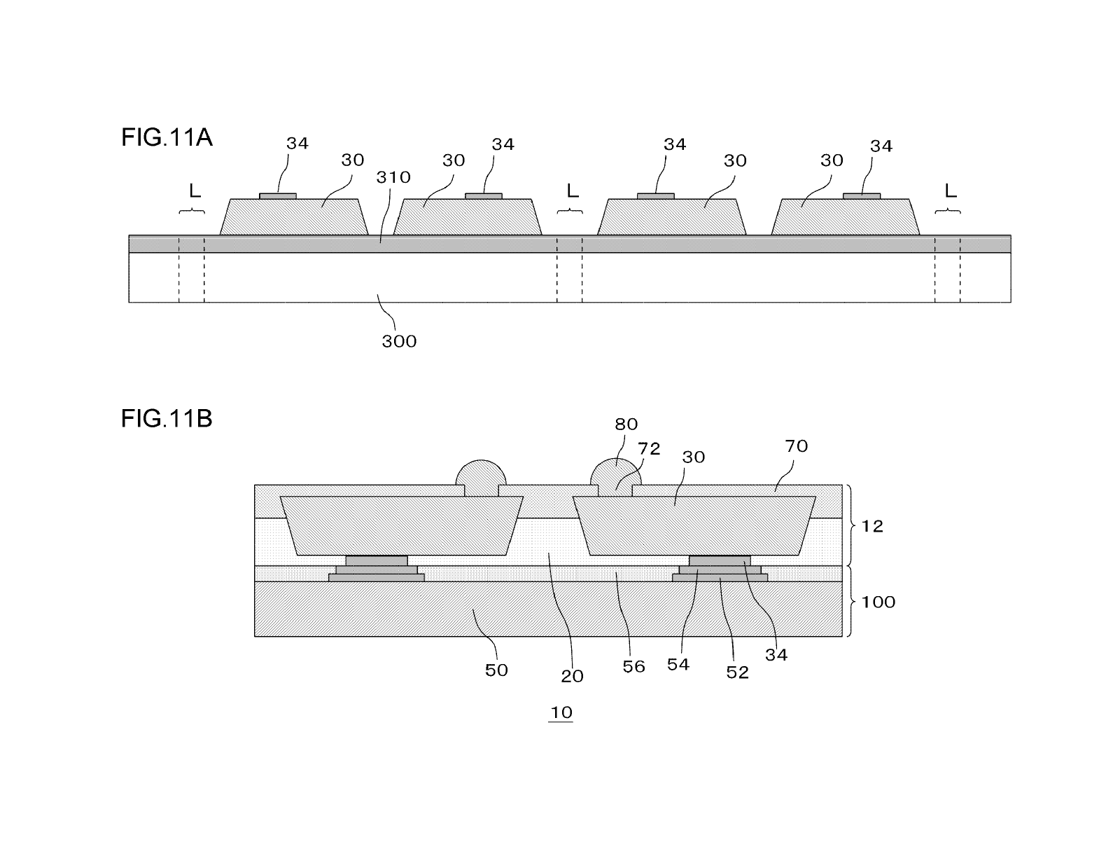

The wiring layers 30 may be formed patterning the copper sheet 200 after the process shown in FIG. 9B (see FIG. 11A). That is, in the fourth method for fabricating a semiconductor module, the bump electrodes are not formed out of the copper sheet 200, and the wiring layers 30 having the same thickness as that of the copper sheet 200 are formed. Subsequently, the processes similar to those shown in FIGS. 4A to 7B may be performed to manufacture a semiconductor module 10 according to a third embodiment as shown in FIG. 11B. In the semiconductor module 10 according to the third embodiment, as shown in 11B, the Au/Ni layer 34 provided on one main surface of the wiring layer 30 connects to the Au/Ni layer 54 of the semiconductor device 100.

In the fourth method for fabricating a semiconductor module, no bump electrodes is formed in the device mounting board 12. Thus, the thickness of the wiring layer 30 can be made equal to the thickness of the copper sheet 200. Thus the wiring layers 30 can be turned into thin film while the occurrence of warping in the semiconductor module 10 is suppressed.

The present invention is not limited to the above-described embodiments only. It is understood that various modifications such as changes in design may be made based on the knowledge of those skilled in the art, and the embodiments added with such modifications are also within the scope of the present invention.

In the above-described first and second embodiments, for example, the bump electrode 32 and the device electrode 52 are electrically connected to each other through the Au—Au bonding connection. However, a Sn (tin) plating layer may be formed, instead, on the top face of the bump electrode 32, so that the bump electrode 32 and the device electrode 52 may be electrically connected through Sn—Au connection. Or, instead of the Au/Ni layer 54, a Cu (copper) layer may be formed on top of the device electrode 52, so that the Cu layer and the bump electrode 32 may be directly bonded to each other through Cu—Cu connection. By employing such bonding methods as those described herein, the amount of Au used can be reduced and thus the manufacturing cost of the semiconductor modules can be reduced. Since Sn is a material that is easily deformable, the variation in height of the bump electrodes 32 is absorbed by the deformation of the Sn layer if the Sn plating layer is used in substitution for the Au/Ni layer. This can suppress the drop in the manufacturing yield of the semiconductor modules caused by the variation in height of the bump electrodes 32.

(Structure of Solar Cell)

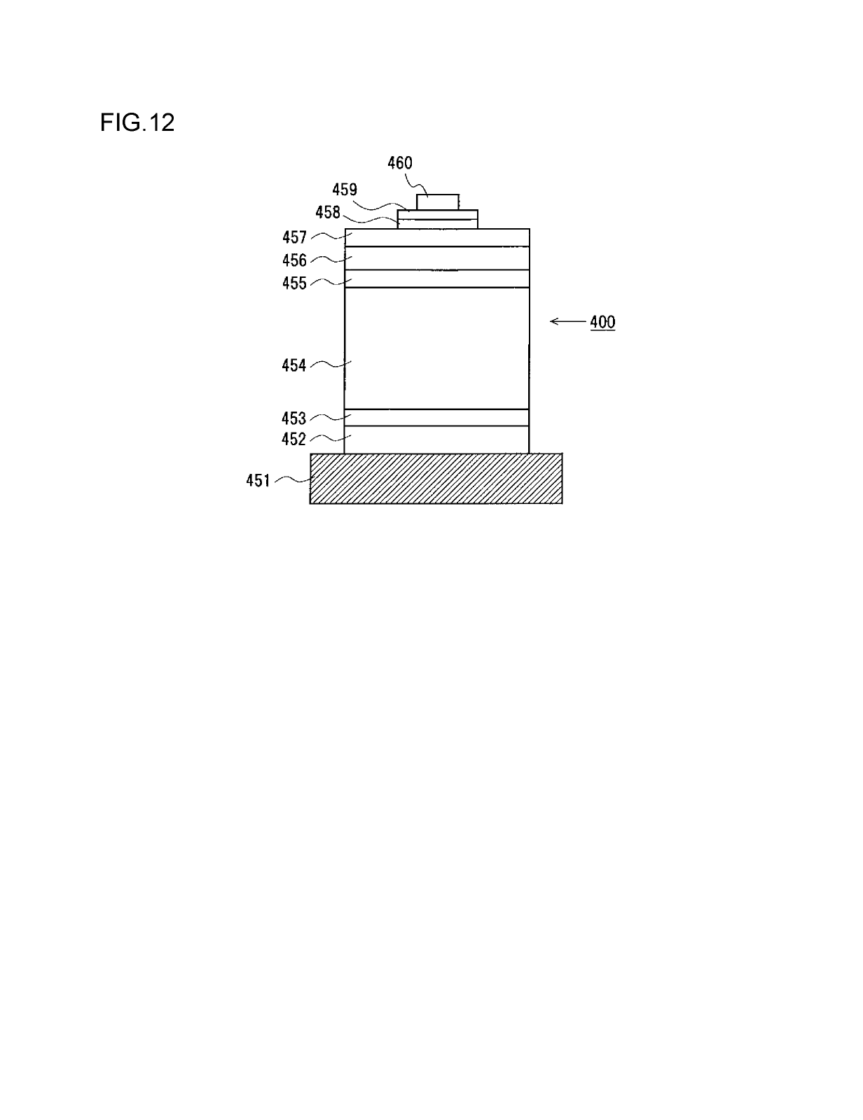

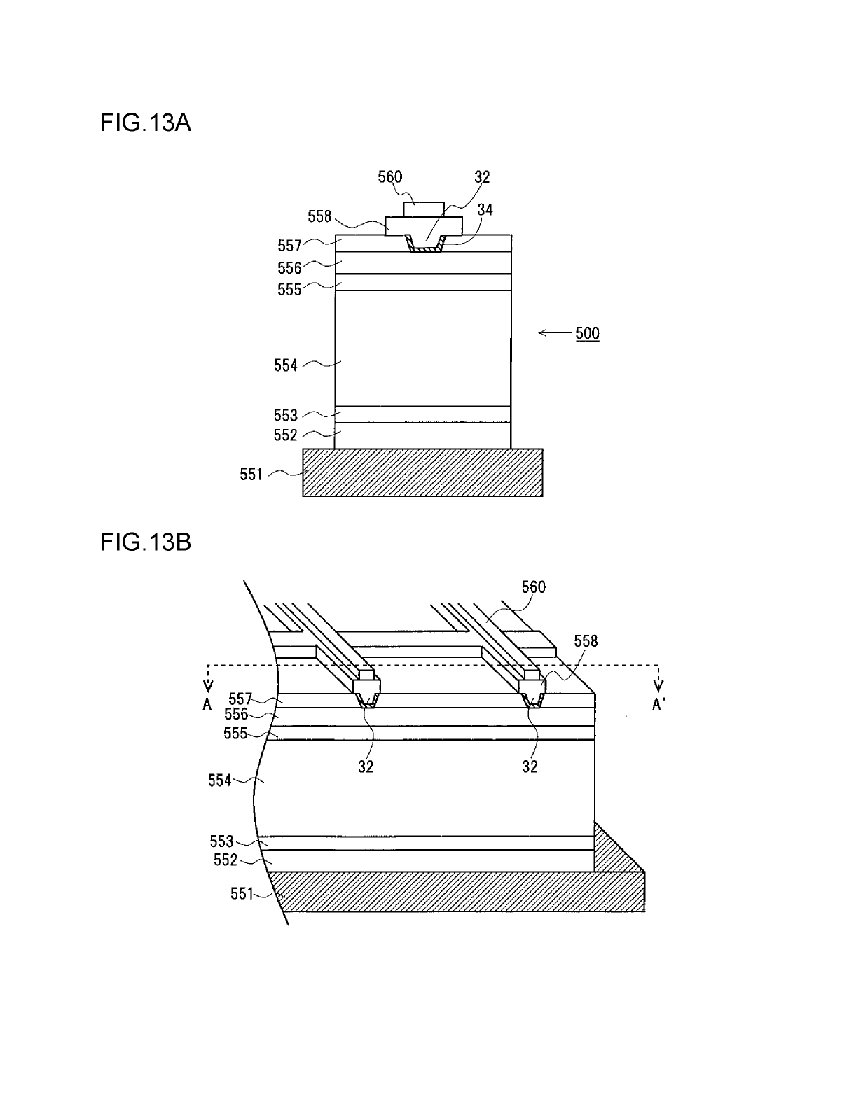

A description is given hereunder of a mode of carrying out the present invention where the present embodiments are used for a solar cell or solar battery. FIG. 12 is a cross-sectional view illustrating a structure of a solar cell in a related art, whereas FIGS. 13A and 13B illustrate an embodiment of the present invention is adopted for a solar cell. A description is first given of a structure of a solar cell. FIG. 12 schematically illustrates a cross-sectional structure of a conventional p-i-n amorphous solar cell. In FIG. 12, the reference number 400 indicates a solace cell body, 451 a substrate, 452 a lower electrode, 453 an n-type semiconductor layer, 454 an i layer, 455 a p layer, 456 a transparent electrode, a passivation layer, 458 an upper electrode, 459 a collecting electrode, and 460 a bus bar. In this configuration as shown in FIG. 12, light enter from above. The substrate 451 may be an electrically conductive element or an alloy of two or more elements selected from among Fe, Ni, Cr, Al, Mo, Au, Pt, Pb, and so forth. Or the substrate 451 may be a heat-resistant synthetic resin film made of polyester, polyethylene, polycarbonate, cellulose acetate, polypropylene, polyvinyl chloride, polyvinylidene chloride, polystyrene, polyamide, polyimide, epoxy or the like, or may be an electrically insulating element such as sheet, glass, or ceramics. If the substrate 451 is electrically insulating, the lower electrode 452 is formed as follows. That is, the lower electrode 452 is formed such that a signal metal or alloy of two or more elements, selected among from Al, Ag, Pt, Au, Ti, W, Fe, Cr, Cu, stainless, SnO₂, In₂O₃, ZnO, ITO and so forth, and a transparent conductive oxide (TCO) are formed on the surface of the substrate 451, k on a side thereof where a deposited film is formed, by using a plating method, an evaporation method, a sputtering method, or the like, for instance. The n layer 453, the i layer 454, and the p layer 455 are fabricated through normal semiconductor manufacturing processes. And these are fabricated using the evaporation method, sputtering method, CVD method, or the like, for instance. A semiconductor material that constitutes the i layer 454 used preferably for the solar cell according to the present embodiment may be amorphous silicon or the like, for instance. A semiconductor material that constitutes the p layer 455 or the n layer 453 used preferably in a photovoltaic device according to the present embodiment may be obtained by doping the amorphous silicon, which constitutes the aforementioned i layer 454, with a valence electron control agent. Also, in order to efficiently absorb light from the sun, a white fluorescent lamp or else through the semiconductor layers, the transparent electrode 456 is desirably characterized such that it exhibits a high transmission rate of light (e.g., 90% or above). Thus, the material suitable for such a transparent electrode may be SnO₂, In₂O₃, ZnO, ITO, and so forth, for instance.

The passivation layer 457 is an insulating material used to prevent a defective part from touching the upper electrode 458, the collecting electrode 459 and the bus bar 460. Also, the passivation layer 457 is laminated entirely on the semiconductor layers and therefore it needs to have optical transparency not to obstruct the incident light of the sun light. Also, in consideration of an environment where it is used as a solar cell outdoors, it is required that the passivation layer 457 be excellent in weather resistance and stable against the humidity and the light. In some instances, the solar cell may be bent or given a shock, so that the passivation layer 457 should also have a certain level of mechanical strength. Such a material may be preferably a polymer resin. More specifically, the material may be polyester, ethylene-vinyl acetate copolymer, acrylate resin, epoxy resin, urethane, and so forth, for instance. The film thickness of the passivation layer 457 may be optional as long as it can keep the electric insulating property and does not fail to have optical transparency. For example, the film thickness thereof may be 3 μm to 5 μm. The upper electrode 458 carries out the same function as that of the collecting electrode 458. A material for the electrode may be, for example, a metal such as Ag, Pt, Cu, and C, or the like. The bus bar 60 is an electrode used to further collect the current flowing through the collecting electrode 459. A material for the bus bar 60 may be a metal such as Ag, Pt, and Cu. A detailed description is now given hereinbelow of a structure of a solar cell according to exemplary embodiments but the present invention is not limited by those exemplary embodiments.

(Method for Manufacturing a Solar Cell)

As shown in FIG. 13, a solar cell having layers structured according to an exemplary embodiment is fabricated as follows. FIG. 13A is a cross-sectional view taken along the line A-A′ of FIG. 13B showing a perspective view of a solar cell. Cr is first deposited to about 1500 angstrom on a SUS substrate 551, which is a 20 cm square and whose thickness is about 0.1 mm, using a sputtering apparatus, thereby forming a lower electrode 552. An N layer 553, an i layer 554 and a p layer 555 are deposited, in this order, on the substrate 551 using a plasma film formation apparatus. Then, an alloy of In and Sn is evaporated using an evaporator and thereby it is deposited to about 700 angstrom on a transparent electrode 556 that serves also as a function of antireflection effect. Then, a passivation layer 557 is deposited, and then upper layers of about 100 μm in width and about 8 cm in length are printed at intervals of 1 cm by using the screen printing method. Then, the device mounting board 12 provided with the supporting base 300 formed through the above described processes in connection with FIG. 2A to FIG. 4C is press-bonded and bonded together to the passivation layer 557. In the present exemplary embodiment, the device mounting board 32 is a copper sheet provided with the bump electrode 32 (covered with the Au/Ni layer 34 on the surface of the bump electrode 32) wherein the bump electrode 32 is formed integrally with the copper sheet. Here, the copper sheet has functions of both the upper electrode and the collecting electrode in a solar cell (hereinafter referred to as “upper electrode 558”).

In the present exemplary embodiment, the material constituting the passivation layer 557 is the same material as that constituting the above-described insulating resin layer 20 in connection with FIG. 2A to FIG. 4C. In other words, used is an insulating resin that develops fluidity when pressurized. A specific press-bonding method is as follows. The bump electrode 32 of the upper electrode 558 faces the passivation layer 557 formed, and the bump electrode 32 and the passivation layer 557 are pressurized from both a substrate 551 side and an upper electrode 558 side. As a result, the bump electrode penetrates the passivation layer 557 made of resin and then reaches the transparent electrode 556. Thereby, the bump electrode 32 and the transparent electrode 556 can be electrically connected.

Referring to FIG. 12 again, the structure of the conventional solar cell is described. In the conventional configuration of the solar cell, the passivation layer 457 has an insulation property or is of high resistivity. This means that even though the upper electrode 458 is laminated on top of the passivation layer 457, the Ohmic contact between the upper electrode 458 and the transparent electrode 456 does not exhibit a sufficient level. Hence, a sufficient amount of current cannot be delivered to the collecting electrode 459. For this reason, the upper electrode 458 must sufficiently be in contact with the transparent electrode 456 and vice versa. More specifically, the passivation layer 457 is impregnated with a conductive paste that contains solvent or unreacted element of a polymer resin, and thereby the passivation layer 457 is so dissolved that the conductive fillers come in contact with the transparent electrode 456. In contrast thereto, according to the exemplary embodiment of the present invention, the bump electrode 32 formed on the upper electrode 558 penetrates the passivation layer 557 with pressurization and then reaches the transparent electrode 556. Hence, the present embodiment electrically connects the bump electrode 32 and the transparent electrode 556 to each other, without the trouble of having to have the passivation layer 557 contain the conductive paste. As shown in FIGS. 13A and 13B, the upper electrode 558 and the transparent electrode 556 are electrically connected to each other and then the bus bar 560 made of a metal such as Ag, Pt and Cu is formed on top of the upper electrode 558. This completes the fabrication of the solar cell.

The features and characteristics of the present invention described based on the embodiments may be defined by the following Item 1 to Item 8:

(Item 1) A semiconductor module including:

an insulating resin layer;

a wiring layer disposed on one main surface of the insulating layer;

a bump electrode protruding on a side of the insulating resin layer from the wiring layer; and

a semiconductor device where a device electrode is disposed counter to the bump electrode,

wherein an end surface of the wiring layer is of a tapered shape such that the end surface thereof enters inside a wiring layer forming region as the end surface thereof approaches the semiconductor device, and

the bump electrode penetrates the insulating resin layer, and the bump electrode and the device electrode are electrically connected to each other.

(Item 2) A semiconductor module according to Item 1, wherein the bump electrode is tapered in the same direction as a tapered direction of the end surface of the wiring layer.
(Item 3) A method, for fabricating a semiconductor module, including:

a process of forming a wiring layer, where a substrate electrode is provided, by selectively removing a metallic sheet held on a supporting base; and

a process of forming a device mounting board, which includes the wiring layer, the substrate electrode, and an insulating resin layer, by forming the insulating resin layer on the supporting base in a manner such that a top face itself of the substrate electrode or a metallic layer disposed on the top face of the substrate electrode is exposed.

(Item 4) A method, for fabricating a semiconductor module, according to Item 3, further including, after the process of forming the device mounting board:

a process of press-bonding the device mounting board and the semiconductor device held by the supporting base in a manner such that a top face itself of the substrate electrode or a metallic layer disposed on the top face of the substrate electrode is electrically connected to a device electrode, of a semiconductor device, disposed counter to the device mounting board; and

a process of removing the supporting base.

(Item 5) A method, for fabricating a semiconductor module, according to any one of Item 2 to Item 4, wherein the process of forming the wiring layer includes a process of forming the wiring layer in a tapered shape such that an end surface of the wiring layer enters inside a wiring layer forming region as the end surface thereof approaches the semiconductor device.
(Item 6) A method, for fabricating a semiconductor module, according to any one of Item 2 to Item 5, wherein the substrate electrode is a bump electrode that is formed integrally with the wiring layer by selectively removing the metallic sheet.
(Item 7) A method, for fabricating a semiconductor module, according to any one of Item 2 to Item 6, wherein the supporting base is transparent, and

wherein, when the device mounting board is press-bonded to the semiconductor device, the device mounting board and the semiconductor device are positioned by verifying the position of the semiconductor device through the supporting base.

(Item 8) A method, for fabricating a semiconductor module, according to any one of Item 2 to Item 7, further including, after the process of press-bonding the semiconductor device to the device mounting board and the process of removing the supporting base:

a process of forming another insulating resin layer in substitution for the insulating resin layer, wherein the another insulating resin layer has a function different from that of insulating resin layer.

What is claimed is:

1. A semiconductor module, comprising:
an insulating resin layer;
a wiring layer disposed on one main surface of said insulating resin layer;
a bump electrode protruding on a side of said insulating resin layer from said wiring layer; and
a semiconductor device where a device electrode is disposed counter to said bump electrode,
wherein said wiring layer has an end surface formed in a tapered shape such that the end surface of said wiring layer enters inside a wiring layer forming region as the end surface thereof approaches the semiconductor device, and
the bump electrode runs through the insulating resin layer, and the bump electrode and the device electrode are electrically connected to each other.

2. A semiconductor module according to claim 1, wherein the bump electrode is tapered in the same direction as a tapered direction of the end surface of the wiring layer.

3. A method, for fabricating a semiconductor module, including:
forming a wiring layer, where a substrate electrode is provided, by selectively removing a metallic sheet held on a supporting base; and
forming a device mounting board, which includes the wiring layer, the substrate electrode, and an insulating resin layer, by forming the insulating resin layer on the supporting base in a manner such that a top face itself of the substrate electrode or a metallic layer disposed on the top face of the substrate electrode is exposed.

4. A method, for fabricating a semiconductor module, according to claim 3, further including, after said forming the device mounting board:
press-bonding the device mounting board and the semiconductor device held by the supporting base in a manner such that a top face itself of the substrate electrode or a metallic layer disposed on the top face of the substrate electrode is electrically connected to a device electrode, of a semiconductor device, disposed counter to the device mounting board; and
removing the supporting base.

5. A method, for fabricating a semiconductor module, according to claim 3, wherein said forming the wiring layer includes forming the wiring layer in a tapered shape such that an end surface of the wiring layer enters inside a wiring layer forming region as the end surface thereof approaches the semiconductor device.

6. A method, for fabricating a semiconductor module, according to claim 4, wherein said forming the wiring layer includes forming the wiring layer in a tapered shape such that an end surface of the wiring layer enters inside a wiring layer forming region as the end surface thereof approaches the semiconductor device.

7. A method, for fabricating a semiconductor module, according to claim 3, wherein the substrate electrode is a bump electrode that is formed integrally with the wiring layer by selectively removing the metallic sheet.

8. A method, for fabricating a semiconductor module, according to claim 4, wherein the substrate electrode is a bump electrode that is formed integrally with the wiring layer by selectively removing the metallic sheet.

9. A method, for fabricating a semiconductor module, according to claim 5, wherein the substrate electrode is a bump electrode that is formed integrally with the wiring layer by selectively removing the metallic sheet.

10. A method, for fabricating a semiconductor module, according to claim 3, wherein the supporting base is transparent, and
wherein, when the device mounting board is press-bonded to the semiconductor device, the device mounting board and the semiconductor device are positioned by verifying the position of the semiconductor device through the supporting base.

11. A method, for fabricating a semiconductor module, according to claim 4, wherein the supporting base is transparent, and
wherein, when the device mounting board is press-bonded to the semiconductor device, the device mounting board and the semiconductor device are positioned by verifying the position of the semiconductor device through the substrate.

12. A method, for fabricating a semiconductor module, according to claim 5, wherein the supporting base is transparent, and
wherein, when the device mounting board is press-bonded to the semiconductor device, the device mounting board and the semiconductor device are positioned by verifying the position of the semiconductor device through the supporting base.

13. A method, for fabricating a semiconductor module, according to claim 3, further including, after said press-bonding the semiconductor device to the device mounting board and said removing the supporting base:
forming another insulating resin layer in substitution for the insulating resin layer, wherein the another insulating resin layer has a function different from that of insulating resin layer.

14. A method, for fabricating a semiconductor module, according to claim 4, further including, after said press-bonding the semiconductor device to the device mounting board and said removing the supporting base:
forming another insulating resin layer in substitution for the insulating resin layer, wherein the another insulating resin layer has a function different from that of insulating resin layer.

15. A method, for fabricating a semiconductor module, according to claim 5, further including, after said press-bonding the semiconductor device to the device mounting board and said removing the supporting base:
forming another insulating resin layer in substitution for the insulating resin layer, wherein the another insulating resin layer has a function different from that of insulating resin layer.
